(19) United States
(12) Patent Application Publication
(10) Pub. No.: US 2023/0166980 A1
(43) Pub. Date: Jun. 1, 2023

(54) GALLIUM-DOPED ZINC OXIDE PARTICLES, FILM CONTAINING GALLIUM-DOPED ZINC OXIDE PARTICLES, TRANSPARENT CONDUCTIVE FILM, ELECTRONIC DEVICE, AND METHOD FOR PRODUCING GALLIUM-DOPED ZINC OXIDE PARTICLES

(71) Applicants: TOHOKU UNIVERSITY, Sendai-shi (JP); NIKON CORPORATION, Tokyo (JP)

(72) Inventors: Kiyoshi KANIE, Sendai-shi (JP); Atsushi MURAMATSU, Sendai-shi (JP); Yasutaka NISHI, Tokyo (JP); Ryoko SUZUKI, Yokohama-shi (JP)

(73) Assignees: TOHOKU UNIVERSITY, Sendai-shi (JP); NIKON CORPORATION, Tokyo (JP)

(21) Appl. No.: 18/075,992

(22) Filed: Dec. 6, 2022

Related U.S. Application Data
(63) Continuation of application No. PCT/JP2021/021397, filed on Jun. 4, 2021.

(30) Foreign Application Priority Data
Jun. 11, 2020 (JP) 2020-101499

(51) Int. Cl. C01G 9/02; C23C 16/40

(52) U.S. Cl. CPC C01G 9/02; C23C 16/40; C01P 2002/54; C01P 2004/64

(57) ABSTRACT

Gallium-doped zinc oxide particles having an average particle diameter of from >0 nm to 30 nm and a resistivity of from 0.08 MΩ·cm to 1.4 MΩ·cm.

### CROSS-REFERENCE TO RELATED APPLICATIONS

This application is a continuation of International Patent Application No. PCT/JP2021/021397 filed on Jun. 4, 2021, which claims the priority benefit of Japanese Patent Application No. 2020-101499 filed on Jun. 11, 2020, the contents of each of which are incorporated herein by reference in their entireties.

### TECHNICAL FIELD

The present invention relates to gallium-doped zinc oxide particles, a film containing gallium-doped zinc oxide particles, a transparent conductive film, an electronic device, and a method for producing gallium-doped zinc oxide particles.

### BACKGROUND ART

Conventionally, a method for producing a ZnO-based thin film as a transparent electrode material by vacuum deposition such as sputtering is known.

### PATENT LITERATURE

PTL 1: Japanese Unexamined Patent Application Publication No. JP 11-236219 A

### SUMMARY OF INVENTION

A first aspect of the present invention is gallium-doped zinc oxide particles having an average particle diameter of from >0 nm to 30 nm and a resistivity of from 0.08 MΩ·cm to 1.4 MΩ·cm.

A second aspect of the present invention is a film containing the above-described gallium-doped zinc oxide particles.

A third aspect of the present invention is a transparent conductive film composed of the above-described film.

A fourth aspect of the present invention is an electronic device equipped with the above-described transparent conductive film.

A fifth aspect of the present invention is a method for producing gallium-doped zinc oxide particles, including: a base introduction process in which a base containing at least sodium methoxide is introduced into a mixed solution containing a zinc raw material, a gallium raw material, and a solvent; a heating process in which a mixed solution introduced the base is heated at a temperature higher than the boiling point of the solvent to obtain gallium-doped zinc oxide particles; and a drying process in which the gallium-doped zinc oxide particles are dried.

A sixth aspect of the present invention is a method for producing a film containing gallium-doped zinc oxide particles, including: a dispersion preparation process in which the gallium-doped zinc oxide particles obtained by the method for producing gallium-doped zinc oxide particles according to the fifth aspect is dispersed in a liquid to obtain a dispersion; a misting process in which the dispersion is misted; and a feeding process in which the misted dispersion is supplied to a base plate.

A seventh aspect of the present invention is a method for producing a film including gallium-doped zinc oxide particles, including: a dispersion preparation process in which gallium-doped zinc oxide particles having an average particle diameter of from >0 nm to 30 nm and a resistivity of from 0.08 MΩ·cm to 1.4 MΩ·cm are dispersed into a liquid to obtain a dispersion; a misting process in which the dispersion is misted; and a feeding process in which the misted dispersion is supplied to a base plate.

A seventh aspect of the present invention is a method for producing a film containing gallium-doped zinc oxide particles, including: a dispersion preparation process in which gallium-doped zinc oxide particles having an average particle diameter of from 10 nm to 15 nm and gallium-doped zinc oxide particles having an average particle diameter of from 16 nm to 36 nm are dispersed in a liquid to obtain a dispersion; and a coating process in which the dispersion is applied.

### BRIEF DESCRIPTION OF DRAWINGS

FIG. 1 is a schematic diagram illustrating one example of a film formation device using a mist method in the present embodiment.

FIG. 2 is a transmission type electron microscope (TEM) photograph of gallium-doped zinc oxide particles.

FIG. 3 is a graph of the resistivity of the film when the film is formed by changing the blending ratio.

FIG. 4 is a graph of the resistivity of the film when the film is formed by changing the heat treatment (annealing) temperature.

### DESCRIPTION OF EMBODIMENTS

Hereinafter, description is made on an embodiment for carrying out the present invention (hereinafter, simply referred to as a “present embodiment”) in detail. The present embodiment described below is an example for describing the present invention, and is not intended to limit the present invention to the contents described below. Note that, in the drawings, a positional relationship in a vertical direction, a horizontal direction, or the like is based on a positional relationship illustrated in the drawings, unless otherwise specified. Further, a dimensional ratio in the drawings is not limited to the illustrated ratio.

### <ZnO: Method for Producing Ga Nanoparticles (Gallium-Doped Zinc Oxide Particles)>

The method for producing gallium-doped zinc oxide particles according to the present embodiment comprises a base introduction process in which a base containing at least sodium methoxide is introduced into a mixed solution containing a zinc raw material, a gallium raw material, and a solvent, a heating process in which the mixed solution introduced the base was heated at a temperature higher than the boiling point of the solvent to obtain zinc·gallium-containing particles, and a drying process in which the obtained particles are dried.

In the conventional synthesis of gallium-doped zinc oxide particles, water formed through the condensation of metal oxides at the initial stage promotes the formation of layered double hydroxides (LDH), which are by-products, and further promotes Ostwald maturation to reduce the amount of gallium ion doping. These behaviors have been a serious problem in obtaining gallium-doped zinc oxide particles having a small particle size and a small resistivity. The present inventors introduce a base including at least sodium methoxide into a mixed solution of zinc and gallium materials dissolved in a solvent selected from the group including methanol, ethanol, ethylene glycol, or a combination thereof, and then the resulting mixed solution at a high temperature higher than the boiling point of the solvent, preferably 200° C. or higher, preferably, by heating and drying etc., for about 24 hours, it has been found that gallium-doped zinc oxide particles doped with a few atomic percentages of Ga can be synthesized. The average particle diameter of the synthesized gallium-doped zinc oxide particles is from >0 nm to 36 nm, preferably from >0 nm to 30 nm, more preferably from >0 nm to 26 nm. The resistivity is from 0.08 MΩ·cm to 1.4 MΩ·cm, preferably from 0.08 MΩ·cm to 1.3 MΩ·cm, more preferably from 0.08 MΩ·cm to 1.0 MΩ·cm.

### <Zinc Raw Material>

In the method of according to the present embodiment, the zinc raw material is not particularly limited, but can include, for example, zinc chloride (ZnCl₂), zinc nitrate (Zn(NO₃)₂), zinc sulfate (ZnSO₄), zinc acetate (Zn(CH₃COO)₂), zinc acetylacetone (Zn(CH₃COCHCOCH₃)₂), hydrates thereof, or combinations thereof.

### <Gallium Raw Material>

In the method of according to the present embodiment, the gallium raw material is not particularly limited, but can include, for example, gallium chloride (GaCl₃), gallium nitrate (Ga(NO)₃), gallium sulfate (Ga₂(SO₄)₃), gallium acetate (Ga(CH₃COO)₃), acetylacetone gallium (Ga(CH₃COCHCOCH₃)₃), hydrates thereof, or combinations thereof.

### <Solvent in Base Introduction Process>

As the solvent in the base introduction process, methanol, ethanol, ethylene glycol, or a combination thereof is used. By using these solvents, it is possible to synthesize more uniform and/or finer gallium-doped zinc oxide particles, i.e., gallium-doped zinc oxide particles with a narrower particle size distribution and/or smaller particle size compared to when using other solvents. Using gallium-doped zinc oxide particles synthesized in this way, a film is formed by using a conventionally known method such as a printing method, or a mist method described later, thereby a film containing gallium-doped zinc oxide having a remarkably improved resistivity can be produced. The solvent may contain a trace amount of water.

### <Base>

In the production method according to the present embodiment, by using at least sodium methoxide (NaOMe) as a base, the formation of layered double hydroxide (LDH) is suppressed to reduce the resistivity, and the gallium-doped zinc oxide particle diameter can be made smaller. In addition, in order to promote Ga doping into the particles, it may be used in combination with other bases, and is not particularly limited, but can include, for example, sodium hydroxide (NaOH), monoethanolamine (H₂NCH₂CH₂OH), or combinations thereof. A base used in combination with sodium methoxide is preferably sodium hydroxide (NaOH). A base containing at least sodium methoxide is introduced into a mixed solution containing a zinc raw material, a gallium raw material, and a solvent.

When sodium methoxide (NaOMe) is used in combination with other bases, the other bases are used R [other bases]/([other bases]+[NaOMe])=from 20 to 80% in a mixed ratio, preferably [other bases]/([other bases]+[NaOMe])=about 60% in a mixing ratio. Preferably, the other base is sodium hydroxide (NaOH).

### <Heating Process>

In the heating process of the production method according to the present embodiment, a mixed solution containing a zinc raw material, a gallium raw material, a solvent, and a base containing at least sodium methoxide is stirred as necessary, etc., and heated at a temperature higher than the boiling point of the solvent, for example, 150° C. or higher, preferably 200° C. or higher, more preferably at a temperature of 230° C. or higher, and generally at a temperature of 350° C. or lower, thereby producing particles containing zinc and gallium. The heating time is 1 hour or more, preferably from 3 to 24 hours, and if the heating time is short, the growth of gallium-doped zinc oxide particles can be suppressed.

### <Drying Process>

In the drying process of the production method according to the present embodiment, particles containing zinc and gallium obtained in the above heating process are washed with alcohol such as ethanol or water such as ion exchange water as necessary, then, for example, under reduced pressure or under normal pressure and dried at a temperature of about from 40° C. to about 150° C. Thus, finally, gallium-doped zinc oxide particles having an average particle diameter of from >0 nm to 36 nm, preferably from >0 nm to 30 nm, more preferably from >0 nm to 26 nm are synthesized.

### <Pressure Powdering Process>

In the Pressure powdering process of the production method according to the present embodiment, a pressure powder of gallium zinc oxide particles can be obtained by applying pressure to the gallium-doped zinc oxide particles obtained in the above drying process to a predetermined shape. The resistivity of the obtained pressure powder is from 0.08 MΩ·cm to 1.4 MΩ·cm, preferably from 0.08 MΩ·cm to 1.3 MΩ·cm, more preferably from 0.08 MΩ·cm to 1.0 MΩ·cm.

In the present embodiment, unless otherwise noted, the “average particle diameter” means the arithmetic average value of the measured value when the constant directional diameter (Feret diameter) of 100 or more randomly selected particles is measured using an electron microscope such as a transmission electron microscope (TEM) and a scanning electron microscope (SEM).

Further, according to the method according to the present embodiment, gallium-doped zinc oxide particles having a Ga dope amount of from >0 mol % to 4.0 mol %, preferably from >0 mol % to 3.5 mol %, more preferably from >0 mol % to 3.0 mol % can be obtained.

In the present embodiment, the “Ga doped amount” refers to the ratio of the gallium atom number to the total number of atoms of zinc atoms and gallium atoms contained in gallium-doped zinc oxide particles. Unless otherwise noted, the “Ga doping amount” in the present embodiment refers to a measurement value when gallium-doped zinc oxide particles are analyzed by an optical method, for example, ICP (inductively coupled plasma) light emission analysis.

### <Method for Producing a Film Containing Gallium-Doped Zinc Oxide>

The first method for producing a film containing gallium-doped zinc oxide according to the present embodiment comprises a dispersion preparation process in which gallium-doped zinc oxide particles having an average particle diameter of from 10 nm to 15 nm, preferably from 12 to 14 nm, and gallium-doped zinc oxide particles having an average particle diameter of from 16 nm to 36 nm, preferably from 20 to 30 nm are dispersed in a liquid to obtain a dispersion, and a coating process in which the dispersion is applied.

Hereinafter, each process will be described.

### [Dispersion Preparation Process]

In the method according to the present embodiment, the above-described gallium-doped zinc oxide particles are introduced into the liquid to prepare the dispersion in the dispersion preparation process. Although not particularly limited, for example, gallium-doped zinc oxide particles can be introduced into the solvent in such an amount that the content of gallium-doped zinc oxide particles in the solvent ranges from 1 to 30 wt % to the total mass of gallium-doped zinc oxide particles and the solvent.

### [Gallium-Doped Zinc Oxide Particles]

Gallium-doped zinc oxide particles introduced into the solvent in the mixing process have an average particle diameter of Ga doped and from >0 nm to 30 nm, preferably from >0 nm to 28 nm, more preferably from >0 nm to 26 nm. The amount of Ga doping in the gallium-doped zinc oxide particles is from >0 mol % to 4.0 mol %, preferably from >0 mol % to 3.5 mol %, more preferably from >0 mol % to 3.0 mol %.

The gallium-doped zinc oxide particles having these characteristics are not particularly limited, but can be synthesized, for example, by the method for synthesizing gallium-doped zinc oxide particles according to the present embodiment described above.

### [Liquid in Dispersion Preparation]

The liquid in the above mixing process is not particularly limited, and examples thereof include an alcohol such as ethylene glycol, water, or a combination thereof. Preferably, the liquid can be ethylene glycol or water.

### [Sonication]

According to the method according to the present embodiment, in the above mixing process, it is preferable to perform sonication in which ultrasonic vibration is applied to a dispersion containing gallium-doped zinc oxide particles and a liquid. By applying ultrasonic vibration to the mixture, gallium-doped zinc oxide particles can be reliably and uniformly dispersed in the liquid.

Any device known to those skilled in the art can be used to impart ultrasonic vibration to the dispersion. Although not particularly limited, examples of such a device include an ultrasonic homogenizer.

The time for applying ultrasonic vibration to gallium-doped zinc oxide particles and the dispersion containing the liquid may be appropriately set in consideration of various parameters such as the type of liquid and the amount of gallium-doped zinc oxide particles introduced into the liquid, and is not particularly limited, for example, from a few minutes to several tens of minutes or several hours, for example, 5 minutes to 3 hours, 10 minutes to 2 hours, or it can be set appropriately within a range of from 10 minutes to 1 hour.

### [Coating Process]

According to the method according to the present embodiment, the above dispersion is applied on the base plate in the coating process.

Application of the dispersion onto the base plate can be carried out by any method known to those skilled in the art. Although it is not particularly limited, for example, the application of the dispersion on the base plate can be performed by a bar coat method, a spin coat method, a dip coating method, a spray coat method, a screen printing method, a gravure printing method, an offset printing method, or an inkjet printing method. By applying the dispersion solution on the base plate in such a method, for example, unlike the case of vacuum film formation such as sputtering, it is possible to produce a film containing gallium-doped zinc oxide at low cost and high yield without using a vacuum device.

### [Base Plate Material]

According to the method according to the present embodiment, a transparent base plate is preferably used as the base plate, and more preferably a glass base plate is used.

### [Heat Treatment Process]

According to the method according to the present embodiment, the base plate after the coating process is optionally dried, for example, in an atmospheric atmosphere for several minutes to several hours, and in the next heat treatment process, it is heat treated in an oxidizing atmosphere or in a reducing atmosphere.

By heat-treating the base plate after the coating process at a predetermined temperature in an oxidizing atmosphere, for example in an atmospheric atmosphere, liquid organic components for example such as ethylene glycol, can be decomposed and removed to form a film containing gallium-doped zinc oxide with gallium-doped zinc oxide particles packed tightly.

Following the above heat treatment in an oxidizing atmosphere, the base plate can be heat treated at a predetermined temperature in a reducing atmosphere, for example, in a hydrogen-containing atmosphere, to form oxygen vacancies in ZnO:Ga and increase the carrier concentration. As a result, the conductivity of the membrane containing the final obtained gallium-doped zinc oxide can be improved, i.e., a lower resistivity can be achieved in the membrane containing the final obtained gallium-doped zinc oxide.

The heat treatment under the oxidizing atmosphere can be carried out for example, at about >200° C., preferably about 300° C. or higher, more preferably about 350° C. or higher or about 400° C. or higher, and about 800° C. or less, preferably about 700° C. or less, more preferably about 600° C. or less or about 500° C. or less, for a predetermined time, for example, about 15 minutes to about 5 hours, preferably about 30 minutes to about 3 hours. Similarly, the heat treatment under the reducing atmosphere can be carried out for example, at about >200° C., preferably about 300° C. or higher, more preferably about 350° C. or higher or about 400° C. or higher, and about 800° C. or less, preferably about 700° C. or less, more preferably about 600° C. or less or about 500° C. or less, for a predetermined time, for example, about 15 minutes to about 5 hours, preferably about 30 minutes to about 3 hours.

The membrane containing gallium-doped zinc oxide obtained by the method according to the present embodiment can be used in any suitable application. In particular, the gallium-doped zinc-containing film exhibits a low resistivity and high transmittance compared to a membrane containing gallium-doped zinc oxide obtained by conventional methods. Therefore, it can be used as a transparent conductive film and a transparent electrode. When a film containing gallium-doped zinc oxide obtained by the method according to the present embodiment is used in an electrode material such as a solar cell, improved performance can be exhibited as compared with the conventional gallium-doped film containing zinc oxide.

### <Method for Producing a Film Containing Gallium-Doped Zinc Oxide by the Mist Film Formation Method>

The second method for producing a film containing gallium-doped zinc oxide according to the present embodiment comprises a dispersion preparation process in which gallium-doped zinc oxide particles having an average particle diameter of from >0 nm to 30, preferably from >0 nm to 28 nm, more preferably from >0 nm to 26 nm and a resistivity of from 0.08 MΩ·cm to 1.4 MΩ·cm, preferably from 0.08 MΩ·cm to 1.3 MΩ·cm, more preferably from 0.08 MΩ·cm to 1.0 MΩ·cm are dispersed into a liquid to obtain a dispersion, a misting process in which the dispersion is misted, a feeding process in which the misted dispersion is supplied to a base plate, and a drying process in which the dispersion present on the base plate is dried after the feeding process.

Since the gallium-doped zinc oxide particles according to the present embodiment have high dispersibility with respect to an aqueous liquid, it is possible to form a nanoparticle film by the method described above. The method for producing a nanoparticle film can be achieved, for example, by spraying a nanoparticle-containing mist obtained by misting (atomizing) a dispersion containing gallium-doped zinc oxide particles by the vibration of the ultrasonic pendulum in the MHz band onto the base plate.

Further, according to the above-described method, since it is not necessary to heat treat the base plate at a high temperature, restrictions on the material of the base plate can be relaxed. For example, film formation is also possible for a flexible base plate made of a resin material having a low softening point.

Hereinafter, each process will be described.

For the dispersion preparation process (1), except for the use of gallium doped zinc oxide particles having an average particle diameter of from >0 nm to 30 nm, preferably from >0 nm to 28 nm, more preferably from >0 nm to 26 nm and a resistivity of from 0.08 MΩ·cm to 1.4 MΩ·cm, preferably from 0.08 MΩ·cm to 1.3 MΩ·cm, more preferably from 0.08 MΩ·cm to 1.0 MΩ·cm, the conditions described in the process performed in the first method of producing a film containing gallium doped zinc oxide described above can be adopted.

As the misting process (2), a method for misting (atomizing) a dispersion containing gallium-doped zinc oxide particles obtained in process (1) may be used.

As the mist generation method, a known method can be employed, and for example, a pressure type, a rotary disc type, an ultrasonic type, an electrostatic type, an orifice vibration type, a steam type, or the like can be employed. In the present embodiment, since it is a dispersion of gallium-doped zinc oxide particles, a technique of physically misting (atomizing) is preferable. Thereby, it is easy to control the temperature of the liquid and the size of the droplets.

In the misting process, by using a carrier gas, the mist of the dispersion can be transported to the subsequent feeding process. As the carrier gas, for example, an inert gas such as argon, helium, or nitrogen can be used.

Further, between the process (2) and (3), a process of uniformizing the mist by the mist trap or a retention process for providing a retention period (residence part) of the mist may be performed.

For the liquid for dispersing the particles, in addition to water, an organic solvent such as ethanol, methanol, or propanol may be used. For example, the above-described (C) component or (D) component can be used as the liquid. One type of liquid may be used alone or may be used in combination of two or more. Further, the frequency band for performing atomization may be suitable for each liquid, and is not limited to the above band. As for the base plate, the material such as glass, resin, metal, etc., is not limited, and it is still desirable to provide a process that can hydrophilize the surface such as UV irradiation.

The supply process (3) is not particularly limited as long as it is a method of supplying mist to the base plate, and a known technique can be employed. For example, a method of spraying minute droplets obtained in the misting process by the mist method on a base plate can be mentioned. Examples of the mist method include ultrasonic spraying, mist CVD method, sonia sauce type, hot wall type, and the like. These methods can be selected in consideration of the film thickness of the film to be formed on the base plate, the size of the droplets to be sprayed, and the like.

The supply process may be any of under atmospheric pressure, reduced pressure, or vacuum, but is preferably under atmospheric pressure from the viewpoint of simplicity.

Further, by spraying the misted dispersion on a base plate masked corresponding to a predetermined pattern, patterning of a film containing gallium-doped zinc oxide particles may be performed. As a result, dimensional control can be performed with high accuracy.

For example, as the masking material, a material that is relatively hydrophilic by light irradiation may be used. By irradiating the material with light corresponding to a predetermined pattern to the material, a region having relative hydrophilicity and a region having water repellency are formed, and by spraying the misted dispersion in this state, the misted dispersion can be placed only in the areas with hydrophilicity.

Furthermore, since the material restriction on the base plate is relaxed, a thin film base plate having high flexibility (sometimes referred to as a “sheet base plate”) can be used as the base plate. In addition, roll-to-roll serial production is also possible.

As the base plate, for example, a known material can be used. Examples include glass, polyethylene terephthalate (PET), polyethylene naphthalate (PEN), polyethersulfone (PES), polyetherimide, polyetheretherketone, polyphenylene sulfide, polyarylate, polyimide, polycarbonate (PC), cellulostriacetate (TAC) cellulose acetate propionate (CAP) etc.

As a drying process (4), the liquid of the dispersion sprayed on the base plate is removed. For example, by vaporizing the liquid by light irradiation such as infrared rays, heating, etc., a film containing gallium-doped zinc oxide particles is formed on the surface of the base plate. The heating temperature can be set taking into account the boiling point of the liquid, the softening point of the base plate, and other physical properties that affect the physical properties of the film. The softening point of the base plate referred to herein refers to a temperature at which the base plate softens and begins to deform when the base plate is heated, and can be obtained, for example, by a test method according to JIS K7191-1.

After the process (4), a UV irradiation process or the like may be performed for the purpose of modifying the base plate such as hydrophilicity impartment as necessary.

Here, an example of a film formation device that can be used in the manufacturing method according to the present embodiment will be described.

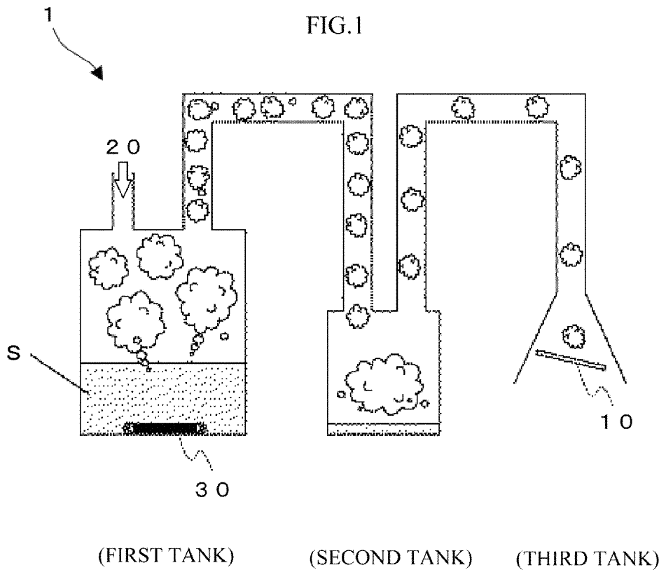

FIG. 1 is a schematic diagram illustrating one example of a film formation device using the mist method in the present embodiment.

A film formation device 1 has a first tank for misting a dispersion containing gallium-doped zinc oxide particles, a second tank being a mist trap for making the mist uniform, and a third tank for spraying mist on a base plate 10.

In the first tank, a dispersion S containing the above-described gallium-doped zinc oxide particles is contained.

In the first tank, air 20 is caused to flow for the purpose of forming a flow path of the mist.

An ultrasonic oscillator 30 is stored in the first tank. The ultrasonic oscillator 30 forms the dispersion containing the gallium-doped zinc oxide particles into mist. A particle diameter of the mist is not particularly limited, and is preferably 10 μm or less (a range of, for example, from 1 μm to 10 μm). The mist generated in the first tank is conveyed to the second tank through a pipe provided to the first tank. In the second tank, excessive mist stagnates in the lower part of the tank, and the mist having a further uniformed particle diameter is conveyed to the third tank through a pipe provided to the second tank. Such configuration that the mist having a particle diameter of 5 μm or less (a range of, for example, from 1 μm to 5 μm) is conveyed from the second tank to the third tank is preferable.

The base plate 10 is arranged in the third tank, the mist conveyed from the second tank is sprayed onto the base plate. In the third tank, the mist is sprayed onto the base plate 10 for a predetermined time period. Further, a dispersion medium in the mist adhering to the base plate 10 is vaporized, and thus a film containing the gallium-doped zinc oxide particles is formed on the surface of the base plate 10. Note that, when a certain time period elapses from the spraying, the mist newly adheres onto the base plate 10 before the mist is vaporized. Thus, the dispersion formed into the liquid droplets flows down, and a uniform film is not formed on the base plate 10. A timing at which spraying of the mist onto the base plate 10 is stopped may be a timing at which the mist containing ZnO:Ga fine particles is liquefied and flows down from the base plate 10 or a timing at which the film having a desired film thickness is formed on the base plate 10.

In the third tank, when the base plate 10 is heated excessively, deformation may be caused due to softening. Thus, in the third tank, the mist is preferably sprayed at temperature lower than the softening point of the base plate, to form the film. Further, when the base plate 10 is heated at predetermined temperature or higher at the time of spraying the mist, the ZnO:Ga fine particles adhering to the base plate 10 are aggregated, as a result, evenness of the film is degraded. Therefore, more preferably, it is configured that the mist is sprayed at a temperature of 40° C. or lower (a range of, for example, from 10° C. to 40° C.), to form the film.

In a case where a film is selectively formed on the base plate 10, when a water-repellent film is selectively formed on the base plate 10 in advance, the mist is placed only in areas that are relatively hydrophilic. In this case, when the base plate 10 is arranged horizontally, it may be difficult for mist adhering to relatively water-repellent areas to repel water, and a film cannot be formed selectively. Thus, in the third tank, the mist is preferably sprayed onto the base plate 10 inclined with respect to the horizontal plane.

Similarly, in the third tank, the mist is preferably sprayed onto the base plate 10 inclined with respect to a plane perpendicular to a spray direction of the mist. This is for the purpose of removing excessing fine particles adhering to areas that are relatively water-repellent, with a blowing force of the mist spray.

Note that the mist trap in the second tank may be omitted in the film formation device.

Further, regarding the method of generating mist, in addition to the above-mentioned method using the ultrasonic oscillator 30, an electrostatic type in which mist is generated by applying a voltage directly to a tube for spraying liquid droplets, a pressurization type in which generated mist scatters by causing gas at a flow rate increased due to pressurization to collide against liquid, a rotary disk type in which liquid droplets drip onto a disk rotating at a high speed to cause generated mist to scatter with a centrifugal force, an orifice oscillation type in which, when liquid droplets are caused to pass through an orifice plate having micro sized pores, the liquid droplets are cut by applying oscillation by a piezoelectric element or the like to generate micro sized liquid droplets, and the like can be adopted. Selection is made as appropriate from those methods of generating mist in accordance with cost, performance, and the like. A plurality of methods may also be combined to generate mist.

A suitable example of a film obtained by the above-described manufacturing method is a membrane containing gallium-doped zinc oxide particles having an average particle diameter of 30 nm or less. Such a film can be suitably used for an antireflection film or the like described later.

The film according to the present embodiment may be a film in which gallium-doped zinc oxide particles are dispersed in a resin material. As the component of the resin material, a suitable component can be selected according to the application of the membrane. Examples of the resin material include polymethyl methacrylate resin.

Further, the base plate after the coating process may optionally be heat-treated in an oxidizing atmosphere or a reducing atmosphere after drying for several minutes to several hours in an atmospheric atmosphere, for example.

The obtained film can be used for transparent conductive films, transparent electrodes, and the like, and can be used for various electronic devices.

### <Anti-Reflective Film>

Since the suitable example of the film according to the present embodiment is a film containing gallium-doped zinc oxide particles, it can be suitably used as an optical thin film that suppresses light scattering, for example. Therefore, the film according to the present embodiment can be suitably used as a layer constituting an antireflection film. Such an antireflection film may have a single-layer structure or may have a multilayer structure having two or more layers. For example, an antireflection film including at least one layer of the film according to the present embodiment may be used.

The antireflection film according to the present embodiment can be provided, for example, on the surface of an optical element such as an optical lens of various optical devices such as a camera or a microscope. Since an optical element such as an optical lens having such an antireflection film suppresses surface reflection, stray light can be removed.

### EXAMPLES

The present embodiment is described in more detail with reference to the following examples and comparative examples, but the present embodiment is not limited to the following examples.

### Example 1

### [Synthesis of Gallium-Doped Zinc Oxide Particles]

In this embodiment, gallium-doped zinc oxide particles were synthesized by the method according to the present embodiment, and the characteristics of the synthesized gallium-doped zinc oxide particles were examined.

### Example 1A

### [Synthesis of Gallium-Doped Zinc Oxide Particles (Base Mixing Ratio: R0.2)]

A methanol solution of 5 mL wherein 60 M of zinc chloride and 10 mol % gallium chloride were dissolved was prepared.

A methanol solution of 5 mL obtained by dissolving sodium hydroxide-sodium methoxide mixed base (mixing ratio R ([sodium hydroxide]/([sodium hydroxide]+[sodium methoxide])))=0.2) was prepared. Zinc chloride, gallium chloride, methanol, sodium hydroxide, and sodium methoxide are manufactured by: FUJIFILM Wako Pure Chemical Corporation.

A methanol solution in which the zinc chloride and the gallium chloride were dissolved and a methanol solution in which the mixed base of R0.2 was dissolved was mixed, stirred for 10 minutes, and then heated at 200° C. for 24 hours.

After washing the mixed solution obtained after heating with ethanol and ion-exchanged water, solid-liquid separation by centrifugation was performed twice. The obtained solid was dried to obtain gallium-doped zinc oxide particles (R0.2).

### Example 1B

### [Synthesis of Gallium-Doped Zinc Oxide Particles (Base Mixing Ratio: R0.4)]

Gallium-doped zinc oxide particles (R0.4) were obtained by the same method as in Example 1A except that a mixed base of R0.4 ([Sodium hydroxide]/([sodium hydroxide]+[sodium methoxide])=0.4) was used.

### Example 1C

### [Synthesis of Gallium-Doped Zinc Oxide Particles (Base Mixing Ratio: R0.6)]

Gallium-doped zinc oxide particles (R0.6) were obtained by the same method as in Example 1A except that a mixed base of R0.6 ([sodium hydroxide]/([sodium hydroxide]+[sodium methoxide])=0.6) was used.

### Example 1D

### [Synthesis of Gallium-Doped Zinc Oxide Particles (Base Mixing Ratio: R0.8)]

Gallium-doped zinc oxide particles (R0.8) were obtained by the same method as in Example 1A except that a mixed base of R0.8 ([sodium hydroxide]/([sodium hydroxide]+[sodium methoxide])=0.8) was used.

### Comparative Example 1

### [Synthesis of Gallium-Doped Zinc Oxide Particles (Sodium Hydroxide Alone: R1.0)]

Gallium-doped zinc oxide particles (R1.0) were obtained by the same method as in Example 1A except that a base of R1.0 was used.

### [Analysis of Gallium-Doped Zinc Oxide Particles]

A pressure powder was obtained by applying pressure to the gallium-doped zinc oxide particles obtained in Example 1 A to D and Comparative Example 1 using a hydraulic pallet press machine to obtain a predetermined shape. The surface resistance of the obtained the pressure powder was measured and the numerical values were compared (Loresta GP MCP-T610, Mitsubishi Chemical Analytech). The results are shown in Table 1.

Referring to Table 1, the average particle diameter of the gallium-doped zinc oxide particles (R0.2) of Example 1A was the smallest, and the resistivity of the gallium-doped zinc oxide particles (R0.8) of Example 1D was the smallest. Further, when only sodium hydroxide was used as a base as in Comparative Example 1, the average particle diameter exceeded 30 nm.

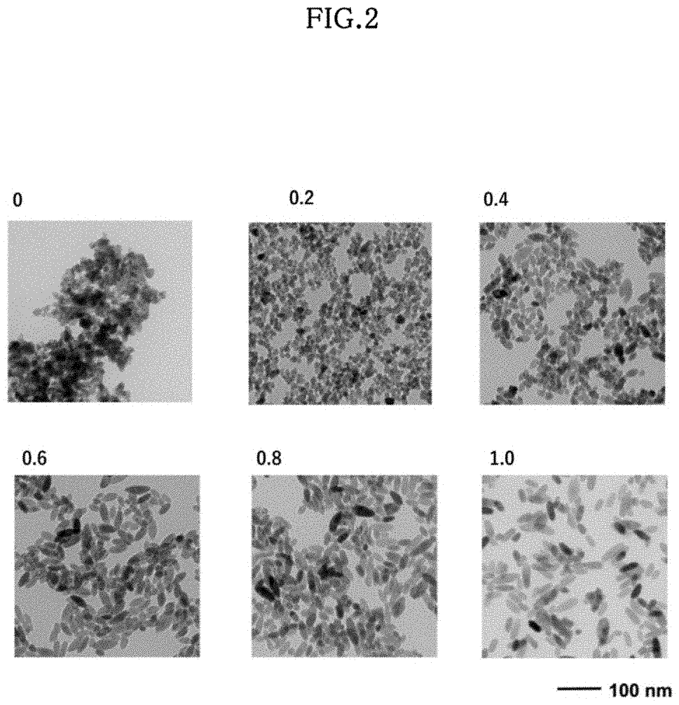

FIG. 2 shows a transmission electron microscope (TEM) photograph of a pressure powder of gallium-doped zinc oxide particles obtained in Examples 1A˜1D and Comparative Example 1. Referring to the TEM photograph of FIG. 2, it can be seen that in Example 1A˜D, very fine particles having an average particle diameter of about 13˜30 nm are synthesized. The amount of Ga doping of these particles analyzed by ICP (inductively coupled plasma) emission analysis was 2.5˜3.3 mol %. The results are shown in Table 1.

TABLE 1

| | | average | | |
|---|---|---|---|---|
| | | particle | Ga³⁺ | |
| Base mixing | [NaOH] | diameter | concentration | resistivity |
| ratio R | (M) | (nm) | (mol %) | (MΩ · cm) |
| Example 1A | 0.76 | 13.9 | 2.8 | 1.30 |
| R0.2 | | | | |
| Example 1B | 1.51 | 21.6 | 3.3 | 0.39 |
| R0.4 | | | | |
| Example 1C | 2.27 | 25.7 | 3.1 | 0.38 |
| R0.6 | | | | |
| Example 1D | 3.02 | 96.0 | 2.9 | 0.37 |
| R0.8 | | | | |
| Comparative | 3.78 | 30.5 | 2.5 | 1.00 |
| Example 1 | | | | |
| R1.0 | | | | |
| (NaOH alone) | | | | |

### Example 2

### [Production of Film Containing Gallium-Doped Zinc Oxide (Formulation of R0.2 Particles and R0.8 Particles)]

In this embodiment, films containing gallium-doped zinc oxide were produced by the mist film formation method according to the present embodiment with a different blending ratio, and the resistivity of the membranes was measured.

### Example 2A

### [Production of Film Containing Gallium-Doped Zinc Oxide (Particle Blending Ratio R0.2:R0.8=0:10)]

Gallium-doped zinc oxide particles having a blending ratio of R0.2:R0.8=0:10 were introduced into water as a liquid in an amount such that it becomes 3 wt % with respect to the total mass of gallium-doped zinc oxide particles and water. The resulting dispersion was then subjected to ultrasonic vibrations for about 30 minutes using an ultrasonic homogenizer to disperse gallium-doped zinc oxide particles well in water.

Next, the obtained dispersion was applied on a glass base plate and then dried in an atmospheric atmosphere. Finally, the glass base plate after application was heat-treated at 300° C., for 1 hour under an atmospheric atmosphere, and then heat treated at 300° C. under an argon-hydrogen (hydrogen 4%) atmosphere for 1 hour to produce a film containing gallium-doped zinc oxide on the glass base plate.

### Example 2B

### [Production of Film Containing Gallium-Doped Zinc Oxide (Particle Blending Ratio R0.2:R0.8=2:8)]

A film containing gallium-doped zinc oxide was produced by the same method as in Example 2A except that the blending ratio of gallium-doped zinc oxide particles was R0.2:R0.8=2:8.

### Example 2C

### [Production of Film Containing Gallium-Doped Zinc Oxide (Particle Blending Ratio R0.2:R0.8=4:6)]

A film containing gallium-doped zinc oxide was produced by the same method as in Example 2A except that the blending ratio of gallium-doped zinc oxide particles was R0.2:R0.8=4:6.

### Example 2D

### [Production of Film Containing Gallium-Doped Zinc Oxide (Particle Blending Ratio R0.2:R0.8=6:4)]

A film containing gallium-doped zinc oxide was produced by the same method as in Example 2A except that the blending ratio of gallium-doped zinc oxide particles was R0.2:R0.8=6:4.

### Example 2E

### [Production of Film Containing Gallium-Doped Zinc Oxide (Particle Blending Ratio R0.2:R0.8=8:2)]

A film containing gallium-doped zinc oxide was produced by the same method as in Example 2A except that the blending ratio of gallium-doped zinc oxide particles was R0.2:R0.8=8:2.

### Example 2F

### [Production of Film Containing Gallium-Doped Zinc Oxide (Particle Blending Ratio R0.2:R0.8=10:0)]

A film containing gallium-doped zinc oxide was produced by the same method as in Example 2A except that the blending ratio of gallium-doped zinc oxide particles was R0.2:R0.8=10:0.

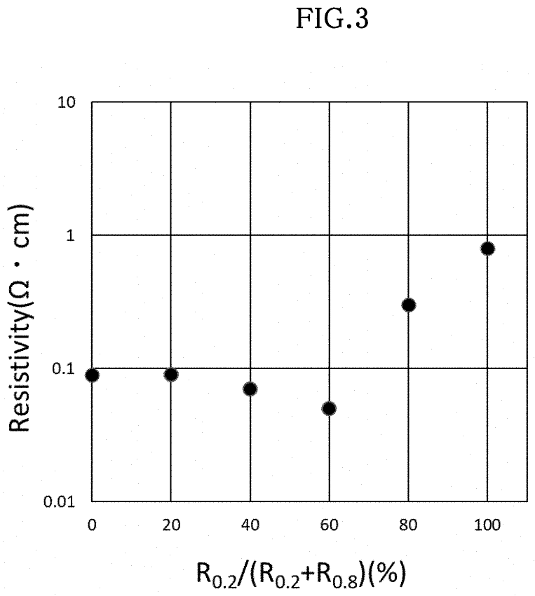

The surface resistance of the film containing gallium-doped zinc oxide obtained in Examples 2A˜2F was measured (Loresta GP MCP-T610, Mitsubishi Chemical Analytech). The results are shown in Table 2 and FIG. 3.

TABLE 2

| blending ratio: | |
|---|---|
| R0.2/(RO.2 + R0.8) (%) | Resistivity (MΩ · cm) |
| Example 2A | 0.09 |
| R0.2 = 0% | |
| Example 2B | 0.09 |
| R0.2 = 20% | |
| Example 2C | 0.07 |
| R0.2 = 40% | |
| Example 2D | 0.05 |
| R0.2 = 60% | |
| Example 2E | 0.3 |
| R0.2 = 80% | |
| Example 2F | 0.8 |
| R0.2 = 100% | |

Referring to Table 2, it was found that the film containing gallium-doped zinc oxide of Example 2D (blending ratio: R0.2/(R 0.2+R0.8)=60%) has the smallest resistivity.

### Example 3

[Production of Film Containing Gallium-Doped Zinc Oxide when the Heat Treatment (Annealing) Temperature is Changed and the Film is Formed]

In this example, a film is produced by changing the heat treatment (annealing) temperature using a dispersion of gallium-doped zinc oxide particles (60%) of R0.2 and gallium-doped zinc oxide particles (40%) of R0.8 prepared by the method according to the present embodiment, and the resistivity of those membranes was measured.

### Example 3A

### [Production of Film at Heat Treatment Process 200° C.]

In the same manner as in Example 2A, a blending of R0.2 gallium doped zinc oxide particles 60% and R0.8 gallium doped zinc oxide particles 40% were dispersed in ethylene glycol. The dispersion was applied on a glass base plate and then dried in an atmospheric atmosphere. Next, the glass base plate after coating was heat-treated at 200° C. for 1 hour under an atmospheric atmosphere, and then heat treated at 200° C. under an argon-hydrogen (hydrogen 4%) atmosphere for 1 hour to produce a film containing gallium-doped zinc oxide on the glass base plate.

### Example 3B

### [Production of Film at Heat Treatment Process 300° C.]

A film containing gallium-doped zinc oxide was produced by the same method as in Example 3A except that the glass base plate after the dispersion application was heat treated at 300° C. under an atmospheric atmosphere for 1 hour, and then heat treated at 300° C. under an argon-hydrogen (hydrogen 4%) atmosphere for 1 hour.

### Example 3C

### [Production of Film at Heat Treatment Process 400° C.]

A film containing gallium-doped zinc oxide was produced by the same method as in Example 3A except that the glass base plate after the dispersion application was heat treated at 400° C. under an atmospheric atmosphere for 1 hour, and then heat treated at 400° C. under an argon-hydrogen (hydrogen 4%) atmosphere for 1 hour.

### Example 3D

### [Production of Film at Heat Treatment Process 500° C.]

A film containing gallium-doped zinc oxide was produced by the same method as in Example 3A except that the glass base plate after the dispersion application was heat treated at 500° C. under an atmospheric atmosphere for 1 hour, and then heat treated at 500° C. under an argon-hydrogen (hydrogen 4%) atmosphere for 1 hour.

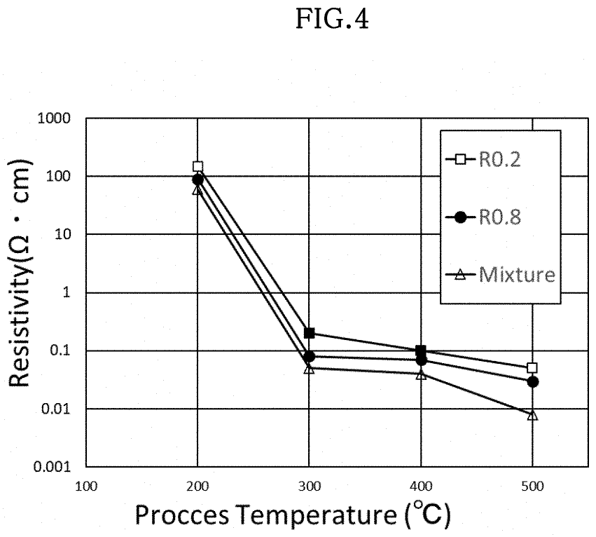

The surface resistance of each of the obtained films containing gallium doped zinc oxide was measured (Loresta GP MCP-T610, Mitsubishi Chemical Analytech). The results are shown in Table 3 and FIG. 4.

TABLE 3

| Process | Resistivity (MΩ · cm) | | |
|---|---|---|---|
| temperature | R0.2 | R0.8 | Mixture |
| Example 3A: 200° C. | 150.00 | 90.00 | 60.000 |
| Example 3B: 300° C. | 0.20 | 0.08 | 0.050 |
| Example 3C: 400° C. | 0.10 | 0.07 | 0.040 |
| Example 3D: 500° C. | 0.05 | 0.03 | 0.008 |

Referring to Table 3, it was found that the resistivity of the film containing gallium-doped zinc oxide obtained above 200° C. was low.

### REFERENCE SIGNS LIST

1 Film formation device
10 Base plate
20 Air
30 ultrasonic oscillator
S Raw material solution

What is claimed is:

1. Gallium-doped zinc oxide particles having an average particle diameter of from >0 nm to 30 nm and a resistivity of from 0.08 MΩ·cm to 1.4 MΩ·cm.

2. The gallium-doped zinc oxide particles according to claim 1, wherein the doped amount of gallium is from >0 mol % to 4.0 mol %.

3. A film containing the gallium-doped zinc oxide particles according to claim 1.

4. A transparent conductive film composed of the film according to claim 3.

5. An electronic device equipped with the transparent conductive film according to claim 4.

6. A method for producing gallium-doped zinc oxide particles, comprising:
a base introduction process in which a base containing at least sodium methoxide is introduced into a mixed solution containing a zinc raw material, a gallium raw material, and a solvent;
a heating process in which a mixed solution introduced the base is heated at a temperature higher than the boiling point of the solvent to obtain gallium-doped zinc oxide particles; and
a drying process in which the gallium-doped zinc oxide particles are dried.

7. A Method for producing gallium-doped zinc oxide particles according to claim 6, further comprising sodium hydroxide as the base.

8. A method for producing gallium-doped zinc oxide particles according to claim 6, wherein the solvent is selected from the group comprising methanol, ethanol, ethylene glycol, and combinations thereof.

9. A method for producing gallium-doped zinc oxide particles according to claim 6, wherein the average particle diameter of the gallium-doped zinc oxide particles is from >0 nm to 30 nm and the resistivity is from 0.08 MΩ·cm to 1.4 MΩ·cm.

10. A method for producing a film containing gallium-doped zinc oxide particles, comprising:
a dispersion preparation process in which the gallium-doped zinc oxide particles obtained by the method for producing gallium-doped zinc oxide particles according to claim 6 is dispersed in a liquid to obtain a dispersion;
a misting process in which the dispersion is misted; and
a feeding process in which the misted dispersion is supplied to a base plate.

11. A method for producing a film containing gallium-doped zinc oxide particles according to claim 10, further comprises a heat treatment process in which a film containing the gallium-doped zinc oxide particles is heat-treated at from >200° C. to 800° C.

12. A method for producing a film comprising gallium-doped zinc oxide particles, comprising:
a dispersion preparation process in which gallium-doped zinc oxide particles having an average particle diameter of from >0 nm to 30 nm and a resistivity of from 0.08 MΩ·cm to 1.4 MΩ·cm are dispersed into a liquid to obtain a dispersion;
a misting process in which the dispersion is misted; and
a feeding process in which the misted dispersion is supplied to a base plate.

13. A method for producing a film containing gallium-doped zinc oxide particles according to claim 12, further comprises a heat treatment process in which a film containing the gallium-doped zinc oxide particles is heat-treated at from >200° C. to 800° C.

14. A method for producing a film containing gallium-doped zinc oxide particles, comprising:
a dispersion preparation process in which gallium-doped zinc oxide particles having an average particle diameter of from 10 nm to 15 nm and gallium-doped zinc oxide particles having an average particle diameter of from 16 nm to 36 nm are dispersed in a liquid to obtain a dispersion, and
a coating process in which the dispersion is applied.

15. A method for producing a film containing gallium-doped zinc oxide particles according to claim 14, further comprises a heat treatment process in which the film containing gallium-doped zinc oxide particles is heat-treated at from >200° C. to 800° C.
